(19) United States
(12) Patent Application Publication
(10) Pub. No.: US 2009/0302714 A1
(43) Pub. Date: Dec. 10, 2009

(54) Piezo-electric composite sensor

(76) Inventor: Dong Guk Kim, Seoul (KR)

Correspondence Address: Lauson & Tarver LLP, 880 Apollo Street, SUITE 301, El Segundo, CA, 90245, US

(21) Appl. No.: 11/916,980

(22) PCT Filed: Jan. 16, 2006
(86) PCT No.: PCT/KR06/00165

§ 371 Date: Dec. 7, 2007

(30) Foreign Application Priority Data
Jun. 10, 2005 (KR) 10-2005-0049729

(51) Int. Cl. H01L 41/187; H01L 41/04; H01L 41/047; H01L 41/24

(52) U.S. Cl. 310/358; 310/365; 310/363; 29/25.35

(57) ABSTRACT

The present invention provides a piezoelectric composite sensor comprising a piezoelectric material layer formed of a piezoelectric composite obtained by mixing piezoelectric material powder with a polymer, and electrodes formed of a conductive composite or conductive polymer obtained by mixing conductive filling particles with a polymer matrix and formed on both surfaces of the piezoelectric material layer. The piezoelectric composite sensor of the present invention has advantages of superior piezoelectric and dielectric properties, high mechanical strength, improved reliability and process flexibility, a simplified process and reduced process costs, and improved productivity.

### CROSS-REFERENCE TO RELATED APPLICATION

This application claims the benefit of the priority filing date of international application no. PCT/KR2006/000165, and Korean application no. (KR)10-2005-0049729 filed Jun. 10, 2005.

### FEDERALLY SPONSORED RESEARCH

Not Applicable

### SEQUENCE LISTING OR PROGRAM

Not Applicable

### STATEMENT REGARDING COPYRIGHTED MATERIAL

Portions of the disclosure of this patent document contain material that is subject to copyright protection. The copyright owner has no objection to the facsimile reproduction by anyone of the patent document or the patent disclosure as it appears in the Patent and Trademark Office file or records, but otherwise reserves all copyright rights whatsoever.

### BACKGROUND

The present invention relates to piezoelectric sensors, and more particularly, to a piezoelectric sensor using a piezoelectric composite.

Functional ceramics with dielectric properties, such as a piezoelectric property and the like, are used in a variety of electric and electronic parts, in a wide range of fields. For instance, functional ceramics are used in piezoelectric elements such as actuators, sensors and resonators. Functional ceramics with a dielectric property include silica (SiO), alumina (AlO), aluminum nitride (AlN), barium titanate (BaTiO) and the like. Functional ceramics with a piezoelectric property include lead zirconate titanate (PZT) and the like.

The piezoelectric property is called piezoelectricity, which is a characteristic by which, upon application of pressure to a piezoelectric element in a certain direction, electricity is generated since dielectric polarization proportional to an external force is produced on both surfaces of the element. On the contrary, if dielectric polarization is generated on the piezoelectric element by means of an electrical method, a force is generated, resulting in deformation of the piezoelectric element. Functional ceramics can be applied to a variety of fields using these characteristics. For example, functional ceramics can be used in manufacturing an ignition device of a gas range, an acceleration sensor, and a sonar device such as a microphone using a mechanical-to-electrical energy conversion characteristic; and in manufacturing an oscillator for a quartz clock, an ultrasonic cleaner and a humidifier using the electrical-to-mechanical energy conversion characteristics.

Crystal, tourmaline, Rochelle salt and the like with the aforementioned piezoelectric properties have been used earlier as piezoelectric elements, and piezoelectric ceramics such as barium titanate are materials with very high conversion efficiency; capable of converting mechanical vibration energy into electrical energy as well as electrical energy into mechanical vibration energy. Particularly, piezoelectric ceramics called lead zirconate titanate (PZT) as a bicomponent material have been found and widely used for sensors such as accelerometers. PZT ceramics have superior mechanical and electrical properties and are prepared by mixing lead titanate (PbTiO) and lead zirconate (PbZrO) at a predetermined ratio. Various physical properties obtained by adding impurities to the mixture according to use thereof can be employed in piezoelectric ceramics.

Generally, these ceramics require a firing process to mold ceramics into a desired shape, and a machining process performed after the firing process. Since ceramics have little plasticity, it is difficult to obtain a molded product with a complicated shape. That is, the ceramics have a disadvantage caused by an insufficient degree of freedom of molding. Accordingly, the ceramics also present the disadvantages of a complicated molding process; low productivity and high molding costs. Furthermore, they may be easily damaged by external impact since the ceramics have low mechanical toughness. Therefore, a technique capable of imparting flexibility and impact resistance to ceramics without affecting the piezoelectric characteristics of the ceramics is required.

Since polymer materials such as plastics have superior moldability properties, they have an advantage in that they can be very precisely molded into complicated shapes at low cost. However, plastics have the disadvantages of low strength, electric conductivity and thermal conductivity. Recently, conductive polymers diversely applicable to a thin film for electromagnetic wave shielding, a secondary battery, sensors, and the like have been proposed. For example, polyparaphenylene, polyvinylidene fluoride (PVDF), polypyrrole, poly-acetylene and the like are conductive polymers that have been put to practical use in the fields of sensors, memory elements and electrode materials.

Particularly, PVDF is a typical polymer with piezoelectric and dielectric properties, which is widely used in electrode molding for secondary batteries.

A piezoelectric composite obtained by mixing ceramics and polymers can employ the advantages of ceramics with a superior piezoelectric property and the advantages of polymers with superior moldability. The piezoelectric composite can function as a piezoelectric sensor when electrodes are formed on both surfaces of the piezoelectric composite.

When electrodes are formed on both surfaces of the piezoelectric composite in the prior art, the electrodes are created by forming a thin metal film or coating metallic ink on the piezoelectric composite. Since this process is an additional process separate from the process of molding a piezoelectric composite, there are problems in that the process is complicated and production costs increase accordingly. Furthermore, since the electrodes are formed into thin metallic films, there are problems in that the electrodes are very fragile, vulnerable to impact, and demonstrate mechanical weakness.

Furthermore, since the electrode material required for implementing a piezoelectric element is not easily coupled or bonded to the piezoelectric composite, the element may not be implemented or the life of a fabricated element may be shortened. Here, the reason why the adhering force of the electrode is important is that an element using piezoelectricity is deformed according to repeated mechanical stress and electrical signals so that the electrode may be delaminated from a piezo-electric polymer through repeated use of the element and proper transmission of an electrical signal may not be performed.

That is, when a metal electrode is used on a piezo-electric composite material, a metallic thin film has a very small thickness and is not easily bonded to the piezoelectric composite material. Thus, there is a problem in that the thin film is de-laminated or is subjected to deterioration of its electrical property upon use thereof.

Furthermore, when a lead wire is fabricated from an electrode made of metal in the prior art, there is troublesomeness in that electrical connection to an external circuit should be made using soldering or a mechanical clip. Since an electrode is formed of metal to have a small thickness, there is a disadvantage of a limited thickness adjustment range of the electrode.

### SUMMARY

The present invention relates to a piezoelectric sensor, and more particularly, a piezo-electric sensor using a piezoelectric composite.

The present invention is conceived to solve the problems in the prior art. An object of the present invention is to provide a piezoelectric composite sensor that has superior piezo-electric and dielectric properties, high mechanical strength, high resistance to impact, and improved reliability.

Another object of the present invention is to provide a piezoelectric composite sensor capable of reducing process costs and improving productivity due to a simplified production process.

### FIGURES

FIG. 1 is a graph illustrating a piezo-electric property of a piezo-electric composite sensor according to the present invention.

FIG. 2 is a sectional view showing a piezo-electric composite sensor according to a preferred embodiment of the present invention.

FIG. 3 is a perspective view showing a piezo-electric composite sensor according to another preferred embodiment of the present invention.

FIG. 4 is a sectional view showing a piezo-electric composite sensor according to a further preferred embodiment of the present invention.

### DESCRIPTION

Technical Problem: The present invention is conceived to solve the problems in the prior art. An object of the present invention is to provide a piezo-electric composite sensor that has superior piezo-electric and dielectric properties, high mechanical strength, high resistance to impact, and improved reliability.

Another object of the present invention is to provide a piezo-electric composite sensor capable of reducing process costs and improving productivity due to a simplified process.

Technical Solution: To achieve these objects, the present invention provides a piezo-electric composite sensor, comprising a pair of electrodes, and a piezo-electric material layer formed of a piezo-electric composite and provided between the electrodes, wherein the piezoelectric composite includes a mixture of piezo-electric material powder and a polymer, and at least one of the electrodes includes a conductive polymer or conductive composite obtained by mixing conductive filling particles with a polymer matrix.

In the piezo-electric composite sensor of the present invention, the pair of electrodes may be formed on both opposite surfaces of the piezo-electric material layer.

In the piezo-electric composite sensor of the present invention, the pair of electrodes may include an inner electrode formed of a metallic electric wire with a predetermined length and an outer electrode formed of the conductive composite or conductive polymer, the piezoelectric material layer may surround the inner electrode, and the outer electrode may surround the piezoelectric material layer. At this time, the piezoelectric composite sensor may further comprise a metallic thin wire longitudinally formed in the outer electrode.

In the piezoelectric composite sensor of the present invention, the pair of electrodes may include a spherical inner electrode formed of metal and an outer electrode formed of the conductive composite or conductive polymer, the piezoelectric material layer may surround the inner electrode, and the outer electrode may surround the piezoelectric material layer except at a predetermined region of the piezoelectric material layer. The piezoelectric composite sensor may further comprise an extension line having one end connected to the inner electrode and the other end exposed to the predetermined region of the piezoelectric material layer while passing through the piezoelectric material layer.

The conductive filling particles contained in the electrodes may include carbon powder or metal powder. The polymer matrix contained in the electrodes may include silicone rubber, polyurethane, polyethylene, polypropylene, poly(ethylene-co-acrylic acid), polyvinylidene fluoride (PVDF), and polytetrafluoroethylene (PTFE).

The piezoelectric material powder may include any one ceramic selected from the group consisting of barium titanate (BaTiO), PbZrO—PbTiO solid solution (PZT), PbZrO 3-PbTiO 3-Pb(^{V}Mg ^{to}1/3 Nb 2ll) solid solution (^{V}PZT-PMN)′, TiO 2, TiO 3, SiO 2, ZnO and SnO 2 Zr, or a mixture thereof.

In the piezoelectric composite sensor of the present invention, the piezoelectric material layer, the electrodes, the inner electrode and the outer electrode may be formed by means of extrusion and injection molding.

Piezoelectric ceramics are utilized very widely all over industries by employing materials with piezoelectric characteristics that enable electrical-to-mechanical energy conversion or mechanical-to-electrical energy conversion.

A piezoelectric sensor according to the present invention is constructed by forming a piezoelectric material layer between two electrodes.

A piezoelectric composite obtained by mixing piezoelectric material powder having a superior piezoelectric characteristic with a polymer having superior moldability is used as the piezoelectric material layer. The piezoelectric composite is prepared by dispersing the piezoelectric material powder into a matrix formed of the polymer. Since the piezoelectric composite is manufactured by dispersing piezoelectric material powder in a matrix formed of a polymer, and extruding and injection molding the piezoelectric composite, the piezoelectric composite can be easily molded, resulting in the inexpensive manufacture thereof.

That is, in a case where ceramics are used as a piezoelectric material, a firing process and a machining process after the firing process is not required. Therefore, in the case of a composite, there are advantages in that articles with various shapes, which cannot be produced by means of the machining process, can be easily molded and productivity can be greatly improved.

Furthermore, although ceramics have problems in that the ceramics are very fragile due to mechanical weakness and vulnerability to impact, the present invention employs the piezoelectric composite as a piezoelectric material layer, thereby ensuring mechanical stability against high impact and improving durability and reliability.

Piezoelectrical performance and machinability of the piezoelectric composite can be controlled by properly adjusting a composition ratio of piezoelectric material powder and a polymer. Although a high content of piezoelectric material powder in the piezoelectric composite is desirable in view of piezoelectrical performance, a too high content of piezoelectric material powder causes loss of fluidity during a molding process, resulting in difficulty in molding the piezoelectric composite. On the other hand, although increase in the content of a polymer improves machinability, it involves loss of a piezoelectric property due to reduction in the content of the piezoelectric material powder. If the content of the polymer is decreased, the piezoelectric property of the piezoelectric composite is improved but the machinability of the piezoelectric composite is reduced. Therefore, in consideration of these conditions, the piezoelectric material powder and the polymer should be mixed at a desirable composition ratio according to required piezoelectric and physical characteristics.

In mixing the piezoelectric material powder with the polymer, it is important to uniformly mix them. Uniform mixing minimizes pores and improves the mechanical properties of a piezoelectric material layer. Therefore, it is desirable to use finer piezoelectric material powder in order to minimize pores through uniform mixing of the piezoelectric material powder and the polymer. If the particle size of the piezoelectric material powder is too large, it is difficult to effectively mix the piezoelectric material powder and the polymer. Thus, there is a problem in that mechanical strength, dispersibility and the like are deteriorated. However, since the piezoelectric property is expected to be deteriorated if the particle size of the piezoelectric material powder is too small, a technique for controlling the particle size in a proper range is required.

The piezoelectric material powder is ceramic powder including at least one metal oxide of titanium (Ti), lead (Pb), barium (Ba), silicon (Si), tin (Sn), magnesium (Mg), niobium (Nb) and zirconium (Zr). Preferably, barium titanate (BaTiO), PbZrO—PbTiO solid solution (PZT), PbZrO—PbTiO—Pb(MgNb) solid solution (PZT-PMN), TiO 3 3 3 1/3 2/3 2, TiO, SiO, ZnO and SnO Zr, or a mixture thereof may be used according to properties of a target piezoelectric element.

Various kinds of polymers including polyurethane, silicone rubber, chloroprene rubber, eccogel, and polyvinylidene fluoride (PVDF) are used as the aforementioned polymer. Particularly, PVDF that is a typical conductive polymer is more preferably used since it has piezoelectric and dielectric properties. The polymer is not limited thereto but may be a piezoelectric polymer including a polymer blend with a PVDF derivative or an additive such as HFP, and vinylidene fluoride/trifluoroethylene (VDF/TrFE).

Furthermore, electrodes of a piezoelectric composite sensor according to the present invention are formed of a conductive polymer or conductive composite obtained by mixing conductive filling particles with a polymer matrix.

Carbon and metal powder with high electrical conductivity is used as the conductive filling particles of the conductive composite or the conductive polymer. Silicone rubber, polyurethane, polyethylene, polypropylene, poly(ethylene-co-acrylic acid), polyvinylidene fluoride (PVDF), polytetrafluoroethylene (PTFE) and the like, which have high crystallinity and a linear chain structure, are mainly used as the polymer matrix.

The formation of electrodes out of a conductive composite or conductive polymer on both surfaces of a piezoelectric composite that is a piezoelectric material layer leads to an advantage in that the electrodes can be manufactured using the same extrusion and injection molding equipment as in the piezoelectric material layer. Therefore, process costs can be reduced, productivity can be improved, and articles with various shapes can be easily molded.

Furthermore, when a lead wire is fabricated from an electrode made of metal in the prior art, the electrical connection to an external circuit should be made using soldering or a mechanical clip. However, in the piezoelectric composite sensor of the present invention, an electrical wire connection can be made directly in the injection molding and extrusion processes. Furthermore, in the present invention, the thickness of an electrode made of a conductive composite or conductive polymer can be controlled so that the thickness adjustment range of the electrode can be increased as compared with a prior art in which external dimensions should be controlled only with a piezoelectric material due to the limitation of thickness of metallic film.

In a conventional case where metal electrodes are used, adhesion of a metallic thin film to a piezoelectric composite is unstable, and the metallic thin film is too thin so that it may become delaminated from the piezoelectric composite upon use thereof. However, since an electrical signal is not properly transmitted if the electrodes are delaminated from the piezoelectric composite, an element may not be implemented or the life of the element may be shortened. Therefore, adhesion of electrodes to a piezoelectric material layer is very important.

Since the piezoelectric material layer and the electrodes contain polymer components in the piezoelectric composite sensor according to the present invention, a very strong binding force between the polymer components maximizes an adhesion between the piezoelectric material layer and the electrodes. By securing stable bonding of a piezoelectric composite and electrodes formed of polymers, the efficiency of an element can be improved and the life of the sensor can be prolonged. These effects can be further enhanced by using the same polymer in the piezoelectric material layer and the electrodes.

Furthermore, since the piezoelectric composite sensor of the present invention is based on a polymer matrix, it has high resistance to thermal and mechanical shock and is mechanically stable. A conventional ceramic-based piezoelectric sensor has problems in that it cannot be easily molded into various shapes and may be very fragile due to mechanical weakness. However, since the piezoelectric composite sensor of the present invention is formed of a polymer-based material, it can be easily molded and maintains mechanical stability even against very high impacts.

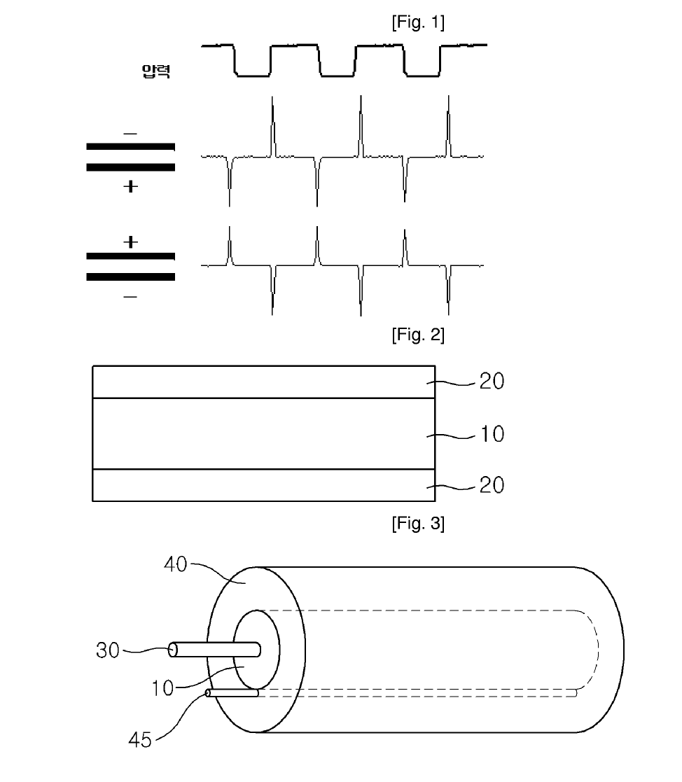

FIG. 1 is a graph illustrating a piezoelectric property of a piezoelectric composite sensor according to the present invention.

Referring to FIG. 1, it can be seen that the piezoelectric composite sensor according to the present invention implements electrical characteristics according to increase and decrease in pressure. In general, a piezoelectric body can be manufactured to be suitable for applications by controlling the direction of polarization. If polarization processing is carried out in a forward polarizing direction, a signal is generated in such a manner that an electrical signal is increased when pressure is increased. If polarization processing is carried out in the opposite direction, a characteristic is exhibited that an electrical signal is decreased when pressure is increased. Therefore, in the piezoelectric composite sensor according to the present invention in which a piezoelectric composite obtained by mixing piezoelectric material powder with a polymer is formed between electrodes formed of a conductive composite or conductive polymer, it can be seen that the piezoelectric property can be controlled by adjusting a polarization direction and the piezoelectric property can be improved.

A piezoelectric composite sensor according to the present invention has the advantages of superior piezoelectric properties and dielectric properties, high mechanical strength, high reliability, and improved process flexibility. Furthermore, the piezoelectric composite sensor according to the present invention also has additional advantages in that it can be easily processed and sensors with various shapes can be manufactured.

Furthermore, according to the present invention, it is possible to simplify a manufacturing process, to reduce process costs and to improve productivity.

### BEST MODE FOR CARRYING OUT THE INVENTION

Hereinafter, preferred embodiments of a piezoelectric composite sensor according to the present invention will be described with reference to the accompanying drawings.

FIG. 2 is a sectional view showing a piezoelectric composite sensor according to a preferred embodiment of the present invention.

Referring to this figure, the piezoelectric composite sensor comprises a piezoelectric material layer 10 and electrodes 20 formed on both surfaces of the piezoelectric material layer.

When the piezoelectric composite sensor constructed as shown in FIG. 2 is applied to a conventional product in which a ceramic material or electrodes may be easily broken, it can improve reliability and durability of the product and prolong the life of the product. For instance, the superior characteristics of this embodiment can be effectively applied to an automobile tire pressure management system that functions to inform drivers of dangerous conditions in advance by sensing a variation in the pressure of an automobile tire.

A method of manufacturing the piezoelectric composite sensor according to the present invention shown in FIG. 2 will be briefly described below.

First, mixing processes of preparing a piezoelectric composite and a conductive composite or conductive polymer, respectively are performed.

A kneading process of loading piezoelectric material powder and a polymer into a kneader and dispersing the piezoelectric material powder in the polymer is performed to obtain a mixture for the piezoelectric composite. As for a piezoelectric material, it is ideal that a high content of piezoelectric material powder is contained to improve a piezoelectric property. Since an excessive amount of piezoelectric material powder limits machinability, however, the content of the piezoelectric material powder should be controlled properly. At this time, since uniform mixing of the piezoelectric material powder and the polymer minimizes pores and improves mechanical properties of a piezoelectric body, the uniform mixing is important.

Furthermore, conductive filling particles and a polymer matrix are hot-mixed using a mixer to obtain the conductive composite or conductive polymer. In the conductive composite or conductive polymer for constructing electrodes, it is ideal that many conductive filling particles are contained therein to improve electrical conductivity. However, the amount of the conductive filling particles should be properly controlled to improve mechanical properties of the electrodes.

The mixed piezoelectric composite is extruded and injection molded using forming equipment.

The mixed conductive composite or conductive polymer is placed and molded on both surfaces of the molded piezoelectric composite, thereby forming electrodes of a piezoelectric composite sensor.

FIG. 3 is a perspective view showing a piezoelectric composite sensor according to another preferred embodiment of the present invention.

Referring to the figure, a piezoelectric sensor comprises an inner electrode 30 formed of a metallic electric wire, a piezoelectric material layer 10 surrounding the inner electrode, and an outer electrode 40 surrounding the piezoelectric material layer. The outer electrode 40 is formed of the aforementioned conductive composite or conductive polymer using the same extrusion and injection molding equipment as in the piezoelectric composite, thereby simplifying the manufacturing process. Furthermore, since the electrode is formed of a polymer-based material, it can be easily processed and have stable mechanical properties even against very high impacts.

The piezoelectric sensor manufactured in the form of an electric wire can be advantageously used in a traffic volume sensor or an overspeed sensor installed across a road. Since the outer electrode formed of the conductive composite or conductive polymer in this embodiment has high resistance to thermal and mechanical impact, the piezoelectric composite sensor of the present invention used as a traffic volume sensor mounted on a road to measure traffic volume by sensing loads of vehicles traveling thereon can sufficiently resist impact due to the loads of the vehicles. Thus, mechanical stability and reliability are improved and the life of the piezoelectric composite sensor can be prolonged.

The piezoelectric composite sensor according to the present invention has a disadvantage in that as the length of the sensor is increased, a resistance value is increased somewhat due to the polymer. However, the resistance value of the piezoelectric composite sensor can be reduced by longitudinally inserting a metallic thin wire 45 into the outer electrode 40 as shown in the figure.

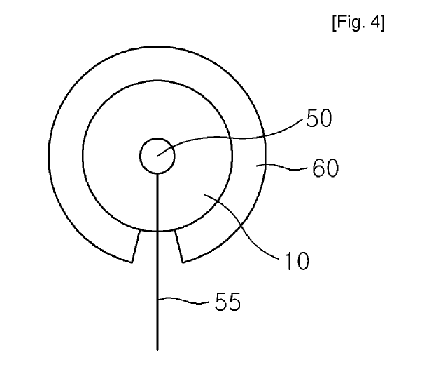

FIG. 4 is a sectional view showing a piezoelectric composite sensor according to a further preferred embodiment of the present invention.

Referring to the figure, a piezoelectric sensor is manufactured in the form of a sphere and comprises an inner electrode 50 formed of metal, a piezoelectric material layer 10 surrounding the inner electrode in a spherical shape, and an outer electrode 60 surrounding the piezoelectric material layer. At this time, the outer electrode 60 is formed on the piezoelectric material layer 10 except a certain region on an outer periphery of the piezoelectric material layer 10, and an extension line 55 connected to the inner electrode 50 and passing through the piezoelectric material layer 10 is exposed to the outside through the region of the piezoelectric material layer on which the outer electrode 60 is not formed. The piezoelectric sensor having such a shape can be used, for example, as a sensor for providing position information in a golf ball simulator or an information device. The piezoelectric sensor can be utilized for desired uses according to various shapes thereof.

According to the present invention described above, electrodes are formed of a conductive composite or conductive polymer on a piezoelectric composite, thereby improving reliability and enabling manufacture of sensors having various shapes.

Although the present invention has been described with reference to the preferred embodiments, it will be understood by those skilled in the art that various modifications and changes can be made thereto without departing from the spirit and scope of the present invention defined by the appended claims.

What is claimed is:

1. A piezoelectric composite sensor, comprising: a pair of electrodes; and a piezoelectric material layer formed of a piezoelectric composite and provided between the electrodes, wherein the piezoelectric composite includes a mixture of piezoelectric material powder and a polymer, and at least one of the electrodes includes a conductive composite or conductive polymer obtained by mixing conductive filling particles with a polymer matrix.

2. The piezoelectric composite sensor of claim 1, wherein the conductive filling particles include carbon powder or metal powder.

3. The piezoelectric composite sensor of claim 1, wherein the polymer matrix includes silicone rubber, polyurethane, polyethylene, polypropylene, poly(ethylene-co-acrylic acid), polyvinylidene fluoride (PVDF), and polytetrafluoroethylene (PTFE).

4. The piezoelectric composite sensor of claim 1, wherein the piezoelectric material powder includes any one ceramic selected from the group consisting of barium titanate (BaTiO), PbZrO—PbTiO solid solution (PZT), PbZrO—PbTiO—Pb(MgNb) solid solution (PZT-PMN), TiO, 3 3 1/3 2/3 2 TiO, SiO, ZnO and SnO Zr₁ or a mixture thereof.

5. The piezoelectric composite sensor of claim 1, wherein the piezoelectric material layer, the electrodes, the inner electrode and the outer electrode are formed by means of extrusion and injection molding.

6. The piezoelectric composite sensor of claim 1, wherein the pair of electrodes is formed on both opposite surfaces of the piezoelectric material layer.

7. The piezoelectric composite sensor of claim 6, wherein the conductive filling particles include carbon powder or metal powder.

8. The piezoelectric composite sensor of claim 6, wherein the polymer matrix includes silicone rubber, polyurethane, polyethylene, polypropylene, poly(ethylene-co-acrylic acid), polyvinylidene fluoride (PVDF), and polytetrafluoroethylene (PTFE).

9. The piezoelectric composite sensor of claim 6, wherein the piezoelectric material powder includes any one ceramic selected from the group consisting of barium titanate (BaTiO), PbZrO—PbTiO solid solution (PZT), PbZrO—PbTiO—Pb(MgNb) solid solution (PZT-PMN), TiO, 3 3 1/3 2/3 2 TiO, SiO, ZnO and SnO Zr, or a mixture thereof.

10. The piezoelectric composite sensor of claim 6, wherein the piezoelectric material layer, the electrodes, the inner electrode and the outer electrode are formed by means of extrusion and injection molding.

11. The piezo-electric composite sensor of claim 1, wherein the pair of electrodes include an inner electrode formed of a metallic electric wire with a predetermined length and an outer electrode formed of the conductive composite or conductive polymer, the piezoelectric material layer surrounds the inner electrode, and the outer electrode surrounds the piezoelectric material layer.

12. The piezoelectric composite sensor of claim 11, wherein the conductive filling particles include carbon powder or metal powder.

13. The piezoelectric composite sensor of claim 11, wherein the polymer matrix includes silicone rubber, polyurethane, polyethylene, polypropylene, poly(ethylene-co-acrylic acid), polyvinylidene fluoride (PVDF), and polytetrafluoroethylene (PTFE).

14. The piezoelectric composite sensor of claim 11, wherein the piezoelectric material powder includes any one ceramic selected from the group consisting of barium titanate (BaTiO), PbZrO—PbTiO solid solution (PZT), PbZrO—PbTiO—Pb(MgNb) solid solution (PZT-PMN), TiO, 3 3 1/3 2/3 2 TiO, SiO, ZnO and SnO Zr, or a mixture thereof.

15. The piezoelectric composite sensor of claim 11, wherein the piezoelectric material layer, the electrodes, the inner electrode and the outer electrode are formed by means of extrusion and injection molding.

16. The piezoelectric composite sensor of claim 11, further comprising a metallic thin wire longitudinally formed in the outer electrode.

17. The piezoelectric composite sensor of claim 16, wherein the conductive filling particles include carbon powder or metal powder.

18. The piezoelectric composite sensor of claim 16, wherein the polymer matrix includes silicone rubber, polyurethane, polyethylene, polypropylene, poly(ethylene-co-acrylic acid), polyvinylidene fluoride (PVDF), and polytetrafluoroethylene (PTFE).

19. The piezoelectric composite sensor of claim 16, wherein the piezoelectric material powder includes any one ceramic selected from the group consisting of barium titanate (BaTiO), PbZrO—PbTiO solid solution (PZT), PbZrO—PbTiO—Pb(MgNb) solid solution (PZT-PMN), TiO, 3 3 1/3 2/3 2 TiO, SiO, ZnO and SnO Zr, or a mixture thereof.

20. The piezoelectric composite sensor of claim 16, wherein the piezoelectric material layer, the electrodes, the inner electrode and the outer electrode are formed by means of extrusion and injection molding.

21. The piezoelectric composite sensor of claim 1, wherein the pair of electrodes include a spherical inner electrode formed of metal and an outer electrode formed of the conductive composite or conductive polymer, the piezoelectric material layer surrounds the inner electrode, the outer electrode surrounds the piezoelectric material layer except a predetermined region of the piezoelectric material layer, and the piezoelectric composite sensor further comprises an extension line having one end connected to the inner electrode and the other end exposed to the predetermined region of the piezoelectric material layer while passing through the piezoelectric material layer.

22. The piezoelectric composite sensor of claim 21, wherein the conductive filling particles include carbon powder or metal powder.

23. The piezoelectric composite sensor of claim 21, wherein the polymer matrix includes silicone rubber, polyurethane, polyethylene, polypropylene, poly(ethylene-co-acrylic acid), polyvinylidene fluoride (PVDF), and polytetrafluoroethylene (PTFE).

24. The piezoelectric composite sensor of claim 21, wherein the piezoelectric material powder includes any one ceramic selected from the group consisting of barium titanate (BaTiO), PbZrO—PbTiO solid solution (PZT), PbZrO—PbTiO—Pb(MgNb) solid solution (PZT-PMN), TiO, 3 3 1/3 2/3 2 TiO, SiO, ZnO and SnO Zr, or a mixture thereof.

25. The piezoelectric composite sensor of claim 21, wherein the piezoelectric material layer, the electrodes, the inner electrode and the outer electrode are formed by means of extrusion and injection molding.
